(19) United States
(12) Patent Application Publication
(10) Pub. No.: US 2026/0052860 A1
(43) Pub. Date: Feb. 19, 2026

(54) DISPLAY PANEL AND DISPLAY APPARATUS

(71) Applicants: KunShan Go-Visionox Opto-Electronics Co., Ltd., Kunshan (CN); Hefei Visionox Technology Co., Ltd., Hefei (CN)

(72) Inventors: Chung-Chun LEE, Kunshan (CN); Yuan YAO, Hefei (CN); Yang SHAO, Kunshan (CN)

(73) Assignees: KunShan Go-Visionox Opto-Electronics Co., Ltd., Kunshan (CN); Hefei Visionox Technology Co., Ltd., Hefei (CN)

(21) Appl. No.: 19/299,262

(22) Filed: Aug. 13, 2025

(30) Foreign Application Priority Data
Aug. 19, 2024 (CN) 202411134931.0

(51) Int. Cl. H10K 59/131; H10K 59/121; H10K 59/122; H10K 59/124

(52) U.S. Cl. CPC H10K 59/131; H10K 59/1213; H10K 59/122; H10K 59/124

(57) ABSTRACT

Embodiments of the present application provide a display panel and a display apparatus. The display panel includes: a substrate; a pixel circuit layer arranged on one side of the substrate, where the pixel circuit layer includes a conductive connection layer, and the conductive connection layer includes at least one power signal line; a first electrode layer arranged on a side of the conductive connection layer away from the substrate, where the first electrode layer includes at least one second wiring structure and a plurality of first electrodes; and an isolation structure arranged on sides of the conductive connection layer and the first electrode layer away from the substrate, where the isolation structure encloses a plurality of isolation openings, the isolation openings expose the corresponding first electrodes, and the isolation structure is electrically connected to the at least one power signal line and the at least one second wiring structure.

### CROSS-REFERENCE TO RELATED APPLICATIONS

The present application claims priority to Chinese Patent Application No. 202411134931.0, titled “DISPLAY PANEL AND DISPLAY APPARATUS” and filed on Aug. 19, 2024, which is hereby incorporated by reference in its entirety.

### FIELD

The present application relates to the field of display devices, and particularly to a display panel and a display apparatus.

### BACKGROUND

Organic light-emitting diodes (OLEDs) and flat panel display apparatuses based on technologies such as light-emitting diodes (LEDs) have been widely applied to various consumer electronics such as mobile phones, televisions, notebook computers and desktop computers and predominate in display apparatuses thanks to their advantages such as high image quality, energy efficiency, slim design and a wide range of applications.

During the preparation of conventional OLED display panels, light-emitting pixel patterning is usually implemented by means of a fine metal mask (FMM). FMM technology is mature and has rich experience in mass production. However, FMM technology also has problems such as limited accuracy, and high costs. Fine metal mask-free technology eliminates the limitations of conventional OLED processes on display size, resolution, and other screen performances, and has the advantages of high performance, full-size coverage, and agile delivery. Patents CN118251982A, CN115666161A, CN116648095A, CN117062489A, CN118678742A, CN118785761A, CN115224220A, CN118678729A, CN118660529A and CN118660589A describe contents related to the fine metal mask-free technology for reference. However, the usage performance of conventional display products needs to be improved.

### SUMMARY

Embodiments of the present application provide a display panel and a display apparatus, with the aim of improving the usage performance of the display panel.

Embodiments of a first aspect of the present application provide a display panel. The display panel includes: a substrate; a pixel circuit layer arranged on one side of the substrate, where the pixel circuit layer includes a conductive connection layer, and the conductive connection layer includes at least one power signal line; a first electrode layer arranged on a side of the conductive connection layer away from the substrate, where the first electrode layer includes at least one second wiring structure and a plurality of first electrodes; and an isolation structure arranged on sides of the conductive connection layer and the first electrode layer away from the substrate, where the isolation structure encloses a plurality of isolation openings, the isolation openings expose the corresponding first electrodes, and the isolation structure is electrically connected to the at least one power signal line and the at least one second wiring structure.

An embodiment of a second aspect of the present application further provides a display apparatus, including a display panel according to any one of the above embodiments of the first aspect.

### BRIEF DESCRIPTION OF THE DRAWINGS

FIG. 1 is a schematic structural diagram of a display panel according to an embodiment of the present application;

FIG. 2 is a cross-sectional view taken along line CC in FIG. 1;

FIG. 3 is a schematic structural diagram of a further display panel according to an embodiment of the present application;

FIG. 4 is a schematic structural diagram of another display panel according to an embodiment of the present application;

FIG. 5 is a schematic structural diagram of yet another display panel according to an embodiment of the present application;

FIG. 6 is a schematic structural diagram of still another display panel according to an embodiment of the present application; and

FIG. 7 is a schematic structural diagram of still yet another display panel according to an embodiment of the present application.

List of reference signs: 10. Active area; 20. Non-active area; 100. Substrate; 200. Conductive connection layer; 201. Power signal line; 202. First wiring structure; 210. First conductive layer; 211. First power signal line; 212. Second air hole; 220. Second conductive layer; 221. Second power signal line; 222. First air hole; 300. First electrode layer; 310. Second wiring structure; 320. First electrode; 400. Isolation structure; 401. Isolation portion; 402. Lap joint portion; 410. First sub-layer; 420. Second sub-layer; 430. Isolation opening; 440. First air vent; 510. First insulation layer; 511. First via; 512. Third via; 513. Second air vent; 520. Second insulation layer; 521. Second via; 530. Third insulation layer; 531. Fourth via; 600. Light-emitting unit; 610. Second electrode; 700. Pixel drive unit; 701. Drive transistor; 710. Semiconductor layer; 720. Gate; 730. Source-drain layer; 731. First terminal; 800. Pixel defining portion; 810. Pixel opening; X. First direction; Y. Second direction; Z. Thickness direction.

### DETAILED DESCRIPTION OF THE EMBODIMENTS

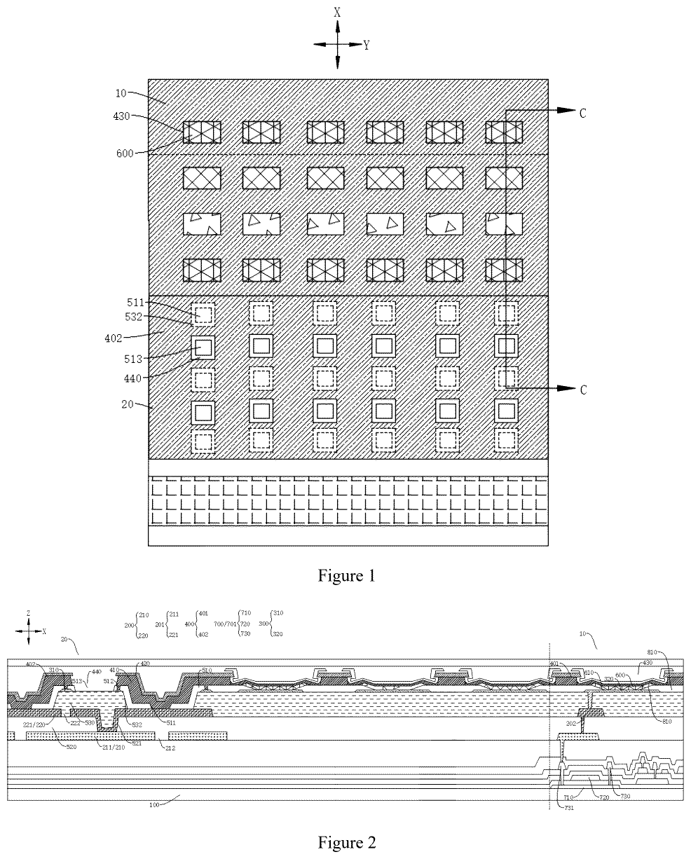

As shown in FIGS. 1 and 2, a display panel according to embodiments of a first aspect of the present application includes: a substrate 100, a pixel circuit layer, a conductive connection layer 200, a first electrode layer 300, and an isolation structure 400, where the pixel circuit layer is arranged on one side of the substrate 100 and includes the conductive connection layer 200, and the conductive connection layer 200 includes at least one power signal line 201; the first electrode layer 300 is arranged on a side of the conductive connection layer 200 away from the substrate 100, and includes at least one second wiring structure 310 and a plurality of first electrodes 320; and the isolation structure 400 is arranged on sides of the conductive connection layer 200 and the first electrode layer 300 away from the substrate 100, the isolation structure 400 encloses a plurality of isolation openings 430, the isolation openings 430 expose the corresponding first electrodes 320, and the isolation structure 400 is electrically connected to the at least one power signal line 201 and the at least one second wiring structure 310.

In the present embodiment, the at least one power signal line 201 may be configured to receive a common voltage signal. The electrical connection between the isolation structure 400 and both the at least one power signal line 201 and the at least one second wiring structure 310 can reduce voltage drop across the power signal line 201, thereby lowering power consumption of the display panel. This enhances the usage performance of the display panel. In one embodiment, the first electrodes 320 may be formed simultaneously with the second wiring structure 310 in the same preparation process, thereby simplifying the preparation process of the display panel.

FIG. 2 is a schematic cross-sectional view of the display panel and does not represent an actual sectional structure.

In one embodiment, as shown in FIG. 2, the isolation openings 430 allow the light-emitting units 600 to be prepared within respective isolation openings 430 to reduce optical crosstalk between respective light-emitting units 600.

In one embodiment, the pixel circuit layer may include a semiconductor layer 710, a gate 720, a source-drain layer 730, a first conductive layer 210, and a second conductive layer 220 sequentially arranged in a direction away from the substrate 100. The conductive connection layer 200 includes the at least one power signal line 201. The power signal line 201 may be arranged in the same layer as at least one of the semiconductor layer 710, the gate 720, the source-drain layer 730, the first conductive layer 210, or the second conductive layer 220. FIG. 2 illustrates the power signal line 201 being located in both the first conductive layer 210 and the second conductive layer 220. Additionally, the power signal line 201 may alternatively be arranged in the same layer as at least one of the semiconductor layer 710, the gate 720, or the source-drain layer 730.

As shown in FIG. 2, in some embodiments, the pixel circuit layer further includes the source-drain layer 730 and a plurality of pixel drive units 700, each pixel drive unit 700 including a drive transistor 701, and a first terminal 731 of the drive transistor 701 being located in the source-drain layer 730, where the conductive connection layer 200 is located on a side of the source-drain layer 730 away from the substrate 100, and the conductive connection layer 200 further includes a plurality of first wiring structures 202; and each first electrode 320 is electrically connected to the first terminal 731 of each corresponding drive transistor 701 through each corresponding first wiring structure 202.

In these embodiments, the conductive connection layer 200 is located on the side of the source-drain layer 730 away from the substrate 100, that is, the power signal line 201 is located on the side of the source-drain layer 730 away from the substrate. This positions the power signal line 201 closer to both the second wiring structure 310 and the isolation structure 400, thereby facilitating electrical connection between the isolation structure 400 and each of the power signal line 201 and the second wiring structure 310. Each pixel drive unit 700 includes each corresponding drive transistor 701, where the first terminal 731 of each corresponding drive transistor 701 is electrically connected to each corresponding first electrode 320 through each corresponding first wiring structure 202 to drive each light-emitting unit 600 to emit light, thereby improving the display effect of the display panel.

In one embodiment, in some other implementations, the pixel circuit layer may include the semiconductor layer 710, the gate 720, and the source-drain layer 730 sequentially arranged in the direction away from the substrate 100. The conductive connection layer 200 includes the at least one power signal line 201. The power signal line 201 may be arranged in the same layer as at least one of the semiconductor layer 710, the gate 720, or the source-drain layer 730 (that is, the conductive connection layer 200 is at least one of the semiconductor layer 710, the gate 720, or the source-drain layer 730). In these implementations, the first terminal 731 of the drive transistor 701 in each pixel drive unit 700 is located in the source-drain layer 730, and is electrically connected to each corresponding first electrode 320 through a via formed in an insulation layer arranged between the source-drain layer 730 and the plurality of first electrodes 320.

As shown in FIGS. 1 and 2, in some embodiments, the display panel includes an active area 10 and a non-active area 20. The plurality of first wiring structures 202 and the plurality of first electrodes 320 are located in the active area 10; and the at least one power signal line 201 and the at least one second wiring structure 310 are located in the non-active area 20.

In these embodiments, the plurality of first wiring structures 202 and the plurality of first electrodes 320 are located in the active area 10, and each pixel drive unit 700 is electrically connected to each corresponding first electrode 320 through each corresponding first wiring structure 202 to drive each corresponding light-emitting unit 600 to emit light, thereby improving the display effect of the display panel. The at least one power signal line 201 and the at least one second wiring structure 310 are located in the non-active area 20, and the second wiring structure 310 is configured to reduce voltage drop across the at least one power signal line 201, thereby lowering power consumption of the display panel.

In one embodiment, as shown in FIG. 2, the isolation structure 400 includes an isolation portion 401 and a lap joint portion 402 electrically connected to the isolation portion 401. The isolation portion 401 is located in the active area 10, the lap joint portion 402 is located in the non-active area 20, and the lap joint portion 402 is electrically connected to the at least one power signal line 201 and the at least one second wiring structure 310. The isolation portion 401 is located in the active area 10, and the lap joint portion 402 is electrically connected to the at least one power signal line 201 and the at least one second wiring structure 310 to transmit an electrical signal in the power signal line 201 to the isolation portion 401.

In one embodiment, as shown in FIG. 2, the isolation portion 401 encloses isolation openings 430 for accommodating the light-emitting units 600.

As shown in FIG. 2, in some embodiments, the conductive connection layer 200 includes a first insulation layer 510. The first insulation layer 510 is arranged between the isolation structure 400 and the first electrode layer 300 and between the at least one power signal line 201 and the isolation structure 400, and the at least one power signal line 201 includes one power signal line 201. The first insulation layer 510 includes at least one first via 511, and the lap joint portion 402 is electrically connected to the at least one power signal line 201 through the at least one first via 511.

In these embodiments, part of the first insulation layer 510 is arranged between the isolation structure 400 and the first electrode layer 300 to electrically isolate the first electrode layer 300 from the isolation structure 400, and another part of the first insulation layer 510 is arranged between the at least one power signal line 201 and the isolation structure 400 to electrically isolate the power signal line 201 from the isolation structure 400. The first insulation layer 510 includes the at least one first via 511, and the lap joint portion 402 is electrically connected to the at least one power signal line 201 through the at least one first via 511, thereby enabling the electrical signal in the power signal line 201 to be transmitted to the lap joint portion 402 and then to be transmitted from the lap joint portion 402 to the isolation portion 401.

As shown in FIG. 2, in some embodiments, the conductive connection layer 200 includes the first conductive layer 210 and the second conductive layer 220 stacked in a direction away from the substrate 100. The at least one power signal line 201 includes: a first power signal line 211 located in the first conductive layer 210; and a second power signal line 221 located in the second conductive layer 220, where the first power signal line 211 is electrically connected to the second power signal line 221.

In these embodiments, the at least one power signal line 201 includes the first power signal line 211 located in the first conductive layer 210, and the second power signal line 221 located in the second conductive layer 220. The first power signal line 211 and the second power signal line 221 are arranged in different layers to increase wiring space availability. The electrical connection between the first power signal line 211 and the second power signal line 221 may further reduce voltage drop across both the first power signal line 211 and the second power signal line 221, thereby lowering power consumption of the display panel.

In one embodiment, as shown in FIG. 2, the conductive connection layer 200 further includes a second insulation layer 520 arranged between the first conductive layer 210 and the second conductive layer 220. The second insulation layer 520 includes at least one second via 521, and the second power signal line 221 is electrically connected to the first power signal line 211 through the at least one second via 521. The second insulation layer 520 is arranged between the first conductive layer 210 and the second conductive layer 220 to mutually insulate and separate the first conductive layer 210 from the second conductive layer 220, and the second power signal line 221 is electrically connected to the first power signal line 211 through the at least one second via 521 to reduce voltage drop across both the first power signal line 211 and the second power signal line 221.

In one embodiment, as shown in FIG. 2, the conductive connection layer 200 includes the first insulation layer 510. The first insulation layer 510 is arranged between the isolation structure 400 and the first electrode layer 300, and between the second conductive layer 220 and the isolation structure 400. The first insulation layer 510 includes the at least one first via 511, and the lap joint portion 402 is electrically connected to the second conductive layer 220 through the at least one first via 511. Part of the first insulation layer 510 is arranged between the second conductive layer 220 and the isolation structure 400 to electrically isolate the second conductive layer 220 from the isolation structure 400. The first insulation layer 510 includes the at least one first via 511, and the lap joint portion 402 is electrically connected to the second conductive layer 220 through the at least one first via 511. In one embodiment, the lap joint portion 402 is electrically connected to the second power signal line 221 through the at least one first via 511, thereby enabling electrical signals in the first power signal line 211 and the second power signal line 221 to be transmitted to the lap joint portion 402 and then to be transmitted from the lap joint portion 402 to the isolation portion 401.

In one embodiment, as shown in FIG. 2, orthographic projections of the at least one first via 511 and the at least one second via 521 on the substrate 100 are arranged in a staggered manner, thereby preventing communication between the first via 511 and the second via 521, so as to avoid an excessive via depth.

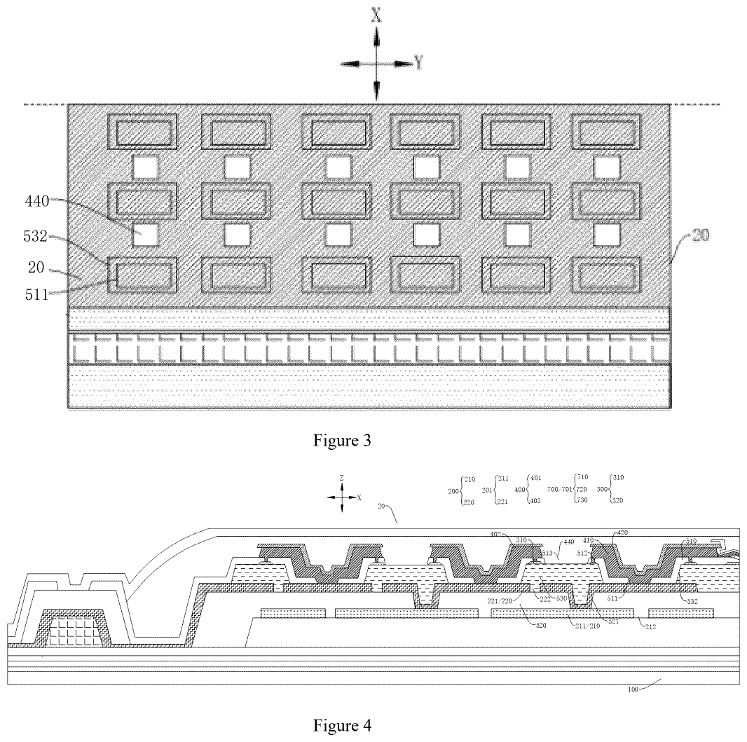

In one embodiment, as shown in FIGS. 3 and 4, the at least one first via comprises a plurality of first vias 511, the plurality of first vias 511 are spaced apart in a first direction X, and the first vias 511 extend in a second direction Y. The first direction X, the second direction Y, and a thickness direction Z of the substrate 100 are mutually perpendicular to each other, thereby enabling a reduced spacing between adjacent first vias 511. The first vias 511 extend in the second direction Y, thereby increasing an aperture size of the first via 511 to enhance a connection area between the second power signal line 221 and the lap joint portion 402.

As shown in FIG. 4, in some embodiments, the second power signal line 221 is formed with at least one first air hole 222, and an orthographic projection of the at least one first air hole 222 on the substrate 100 and an orthographic projection of the first via 511 on the substrate 100 are arranged in a staggered manner.

In these embodiments, the first air hole 222 is configured to exhaust gas from a side of the second power signal line 221 facing the substrate 100 through the first air hole 222. The orthographic projection of the first air hole 222 on the substrate 100 and the orthographic projection of the first via 511 on the substrate 100 are arranged in a staggered manner, that is, the first air hole 222 and the first via 511 are not in communication with each other. Since no conductive material is arranged at the location of the first air hole 222, electrical connection cannot be established, and the arrangement in a staggered manner between the first air hole 222 and the first via 511 ensures that the second power signal line 221 maintains contact with the lap joint portion 402, thereby reducing a risk of disconnection between the second power signal line 221 and the lap joint portion 402.

In one embodiment, as shown in FIG. 4, the first power signal line 211 is formed with at least one second air hole 212, and an orthographic projection of the at least one second air hole 212 on the substrate 100 and an orthographic projection of the second via 521 on the substrate 100 are arranged in a staggered manner. The second air hole 212 is configured to exhaust gas from a side of the first power signal line 211 facing the substrate 100 through the second air hole 212. The orthographic projection of the second air hole 212 on the substrate 100 and the orthographic projection of the second via 521 on the substrate 100 are arranged in a staggered manner, that is, the second air hole 212 and the second via 521 are not in communication with each other. Since no conductive material is arranged at the location of the second air hole 212, electrical connection cannot be established, and the arrangement in a staggered manner between the second air hole 212 and the second via 521 ensures that the second power signal line 221 maintains contact with the first power signal line 211, thereby reducing a risk of disconnection between the first power signal line 211 and the second power signal line 221.

As shown in FIG. 4, in some embodiments, the first insulation layer 510 includes at least one third via 512, and the lap joint portion 402 is electrically connected to the at least one second wiring structure 310 through the at least one third via 512.

In these embodiments, the lap joint portion 402 is electrically connected to the at least one second wiring structure 310 through the at least one third via 512, and the lap joint portion 402 is electrically connected to both the second power signal line 221 and the first power signal line 211, thereby further reducing voltage drop across both the first power signal line 211 and the second power signal line 221.

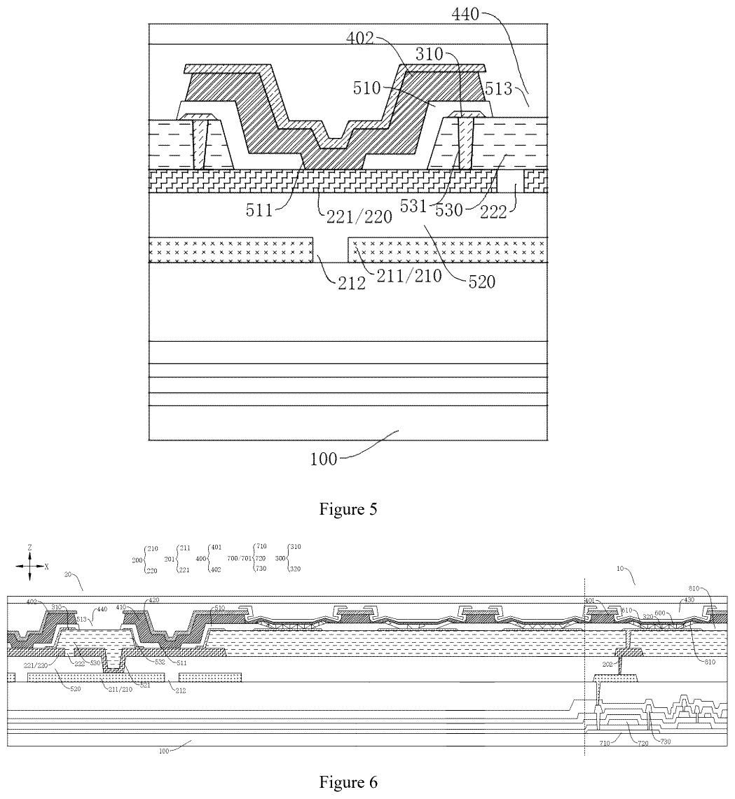

As shown in FIGS. 2 and 5, in some other embodiments, the conductive connection layer 200 further includes a third insulation layer 530 arranged between the first electrode layer 300 and the at least one power signal line 201.

In these embodiments, the third insulation layer 530 is arranged between the first electrode layer 300 and the at least one power signal line 201, the third insulation layer 530 is arranged on a side of the first electrodes 320 and the second wiring structure 310 facing the substrate 100, and the third insulation layer 530 is located between the at least one second wiring structure 310 and the at least one power signal line 201, so as to mutually insulate and separate the second wiring structure 310 from the at least one power signal line 201.

In one embodiment, as shown in FIG. 5, the third insulation layer 530 includes at least one fourth via 531, and the second wiring structure 310 is electrically connected to the at least one power signal line 201 through the fourth via 531. The at least one second wiring structure 310 is electrically connected to the at least one power signal line 201 through the fourth via 531, thereby reducing voltage drop across the at least one power signal line 201. Unlike the above-mentioned embodiments, in this embodiment, the at least one second wiring structure 310 does not need to be connected to the power signal line 201 through the lap joint portion 402.

In one embodiment, the second wiring structure 310 is electrically connected to the first power signal line 211 or the second power signal line 221 through the fourth via 531.

In some other embodiments, as shown in FIG. 6, the third insulation layer 530 includes at least one fifth via 532, and the second wiring structure 310 extends through the fifth via 532 to be electrically connected to the at least one power signal line 201. In one embodiment, as shown in FIG. 2, part of the first insulation layer 510 is located in the fifth via 532 and includes the at least one first via 511 located within the fifth via 532. The isolation structure 400 is electrically connected to the at least one power signal line 201 through the at least one first via 511. In one embodiment, the lap joint portion 402 is located within the fifth via 532 and is electrically connected to the at least one power signal line 201 through the first via 511.

In one embodiment, as shown in FIG. 6, part of the second wiring structure 310 is located between the first insulation layer 510 and the at least one power signal line 201.

In these embodiments, part of the first insulation layer 510 is located within the fifth via 532, and another part of the isolation structure 400 is located within the fifth via 532 and is electrically connected to the at least one power signal line 201 through the first via 511. The at least one power signal line 201 may be the second power signal line 221.

As shown in FIG. 2, in some embodiments, each pixel drive unit 700 includes at least one switching transistor, and the conductive connection layer 200 further includes a plurality of third wiring structures, where each third wiring structure is electrically connected to each corresponding drive transistor 701 and the at least one corresponding switching transistor.

In these embodiments, each third wiring structure is electrically connected to each corresponding drive transistor 701 and the at least one corresponding switching transistor, thereby enabling an electrical signal to be provided to the drive transistor 701 and the switching transistor through the third wiring structure, so as to illuminate each light-emitting unit 600 through each corresponding first electrode 320.

Each first wiring structure 202 is configured to electrically connect each corresponding drive transistor 701 to each corresponding first electrode 320, and each third wiring structure is configured to be electrically connected to each corresponding drive transistor 701 and the at least one corresponding switching transistor to provide the electrical signal. The drive transistor 701 includes the semiconductor layer 710, the gate 720, and the source-drain layer 730 sequentially arranged in the direction away from the substrate 100. The conductive connection layer 200 is arranged on the side of the source-drain layer 730 away from the substrate 100. The source-drain layer 730 includes sources and drains, where the sources are the first terminals 731. Each first wiring structure 202 is electrically connected between each corresponding source and each corresponding first electrode 320, and each third wiring structure is electrically connected to each corresponding source and drain of the drive transistor 701 and each corresponding source and drain of the switching transistor.

In one embodiment, the display panel may be any one of a 2T1C circuit, a 7T1C circuit, a 7T2C circuit, or a 9T1C circuit. As used herein, “2T1C circuit” refers to a circuit including two transistors and one capacitor, and other terms including “7T1C circuit”, “7T2C circuit”, “9T1C circuit”shall be construed accordingly.

As shown in FIG. 2, in some embodiments, the display panel further includes a light-emitting layer and a pixel defining layer. The pixel defining layer is arranged between the first electrodes 320 and the isolation structure 400, the pixel defining layer includes pixel defining portions 800 and pixel openings 810, the pixel openings 810 are in communication with the corresponding isolation openings 430, and the pixel openings 810 expose the corresponding first electrodes 320. The light-emitting layer includes light-emitting units 600 respectively located in the corresponding pixel openings 810, and the light-emitting units 600 are arranged on a side of the first electrodes 320 away from the substrate 100.

In these embodiments, the pixel defining layer includes the pixel defining portions 800 and the pixel openings 810. The pixel openings 810 are in communication with the corresponding isolation openings 430. The light-emitting layer includes the light-emitting units 600 respectively located in the pixel openings 810, and the light-emitting units 600 are arranged on the side of the first electrodes 320 away from the substrate 100. The isolation structure 400 and the pixel defining portions 800 are configured to reduce optical crosstalk between different light-emitting units 600.

In one embodiment, the pixel defining portions 800 are made of the same material as the first insulation layer 510, thereby enabling simultaneous preparation in a single preparation process to reduce preparation difficulty.

In one embodiment, as shown in FIG. 2, second electrodes 610 are arranged on a side of the corresponding light-emitting units 600 away from the substrate 100, where the first electrodes 320 and the second electrodes 610 collectively drive the light-emitting units 600 to emit light.

In one embodiment, as shown in FIG. 2, the second electrodes 610 are electrically connected to the isolation structure 400. Specifically, the second electrodes 610 are electrically connected to the isolation portion 401, thereby transmitting the electrical signal in the at least one power signal line 201 to the second electrode 610.

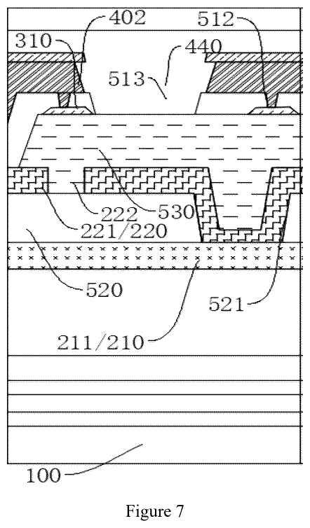

As shown in FIG. 7, in some embodiments, the lap joint portion 402 encloses a first air vent 440, and an orthographic projection of the first air vent 440 on the substrate 100 and an orthographic projection of the second via 521 on the substrate 100 are arranged in a staggered manner.

In these embodiments, the first air vent 440 is configured to allow gas transmission from a side of the lap joint portion 402 facing the substrate 100. Since no material of the lap joint portion 402 is present at the location of the first air vent 440, the arrangement in a staggered manner between the first air vent 440 and the second via 521 ensures that the lap joint portion 402 is electrically connected to the at least one power signal line 201.

In one embodiment, as shown in FIG. 7, the first insulation layer 510 is formed with a second air vent 513, and an orthographic projection of the second air vent 513 on the substrate 100 is located within the orthographic projection of the first air vent 440 on the substrate 100. The first insulation layer 510 is formed with the second air vent 513 located within the first air vent 440, thereby enabling gas to be exhausted through both the second air vent 513 and the first air vent 440.

As shown in FIG. 2, in some embodiments, the isolation structure 400 includes a first sub-layer 410 and a second sub-layer 420. The first sub-layer 410 is located on a side of the second sub-layer 420 facing the substrate 100, and an orthographic projection of the first sub-layer 410 on the substrate 100 is located within an orthographic projection of the second sub-layer 420 on the substrate 100.

In these embodiments, the orthographic projection of the first sub-layer 410 on the substrate 100 is smaller than the orthographic projection of the second sub-layer 420 on the substrate 100, thereby forming a recess beneath the second sub-layer 420. During preparation of the light-emitting units 600, materials of the light-emitting layer may be separated by the isolation structure 400 into independent light-emitting units 600, eliminating the need for fine mask evaporation processes, thereby reducing preparation costs.

In one embodiment, as shown in FIG. 2, the first sub-layer 410 is connected to the at least one power signal line 201 through a via, thereby reducing voltage drop across the at least one power signal line 201 and transmitting the electrical signal to the isolation structure 400.

In one embodiment, as shown in FIG. 2, the first sub-layer 410 is connected to the at least one second wiring structure 310 through a via, thereby further reducing voltage drop across the at least one power signal line 201.

An embodiment in a second aspect of the present application further provides a display apparatus, including a display panel according to any one of the above-described embodiments in the first aspect. Since the display apparatus according to the embodiment in the second aspect of the present application includes the display panel according to any one of the above-described embodiments in the first aspect, the display apparatus according to the embodiment in the second aspect of the present application has the beneficial effects of the display panel according to any one of the above-described embodiments in the first aspect, which will not be repeated herein.

The display apparatus in the embodiments of the present disclosure includes, but is not limited to, devices having a display function, such as a mobile phone, a personal digital assistant (PDA), a tablet computer, an e-book reader, a television, an access control system, a smart fixed-line telephone, or a console.

Although the present application is described with reference to the embodiments, various modifications can be made, and equivalents can be provided to substitute for the components thereof without departing from the scope of the present application. In particular, the features mentioned in the embodiments can be combined in any manner, provided that there is no structural conflict. The present application is not limited to the specific embodiments disclosed herein but includes all the embodiments that fall within the scope of the claims.

What is claimed is:

1. A display panel, comprising:
a substrate;
a pixel circuit layer arranged on one side of the substrate, wherein the pixel circuit layer comprises a conductive connection layer, and the conductive connection layer comprises at least one power signal line;
a first electrode layer arranged on a side of the conductive connection layer away from the substrate, wherein the first electrode layer comprises at least one second wiring structure and a plurality of first electrodes; and
an isolation structure arranged on sides of the conductive connection layer and the first electrode layer away from the substrate, wherein the isolation structure encloses a plurality of isolation openings, the isolation openings expose the corresponding first electrodes, and the isolation structure is electrically connected to the at least one power signal line and the at least one second wiring structure.

2. The display panel according to claim 1, wherein the pixel circuit layer further comprises a source-drain layer and a plurality of pixel drive units, each pixel drive unit comprising a drive transistor, and a first terminal of the drive transistor being located in the source-drain layer, wherein
the conductive connection layer is located on a side of the source-drain layer away from the substrate, and the conductive connection layer further comprises a plurality of first wiring structures; and
each first electrode is electrically connected to the first terminal of each corresponding drive transistor through each corresponding first wiring structure.

3. The display panel according to claim 2, wherein the display panel comprises an active area and a non-active area, wherein
the plurality of first wiring structures and the plurality of first electrodes are located in the active area; and
the at least one power signal line and the at least one second wiring structure are located in the non-active area.

4. The display panel according to claim 3, wherein the isolation structure comprises an isolation portion and a lap joint portion electrically connected to the isolation portion, wherein the isolation portion is located in the active area and the lap joint portion is located in the non-active area, and the lap joint portion is electrically connected to the at least one power signal line and the at least one second wiring structure; and
the isolation portion encloses the plurality of isolation openings.

5. The display panel according to claim 3, wherein the conductive connection layer comprises a first insulation layer, the first insulation layer being arranged between the isolation structure and the first electrode layer and between the at least one power signal line and the isolation structure, and the at least one power signal line comprising one power signal line, wherein
the first insulation layer comprises at least one first via, and the lap joint portion is electrically connected to the at least one power signal line through the at least one first via.

6. The display panel according to claim 3, wherein the conductive connection layer comprises a first conductive layer and a second conductive layer stacked in a direction away from the substrate, and the at least one power signal line comprises:
a first power signal line located in the first conductive layer; and
a second power signal line located in the second conductive layer,
wherein the first power signal line is electrically connected to the second power signal line.

7. The display panel according to claim 6, wherein the conductive connection layer further comprises a second insulation layer arranged between the first conductive layer and the second conductive layer, wherein the second insulation layer comprises at least one second via, and the second power signal line is electrically connected to the first power signal line through the at least one second via.

8. The display panel according to claim 7, wherein the conductive connection layer comprises a first insulation layer arranged between the isolation structure and the first electrode layer and between the second conductive layer and the isolation structure, wherein
the first insulation layer comprises at least one first via, and the lap joint portion is electrically connected to the second conductive layer through the at least one first via.

9. The display panel according to claim 8, wherein orthographic projections of the at least one first via and the at least one second via on the substrate are arranged in a staggered manner; and
the at least one first via comprises a plurality of first vias, wherein the plurality of first vias are spaced apart in a first direction, the first vias extend in a second direction, and the first direction, the second direction, and a thickness direction of the substrate are mutually perpendicular to each other.

10. The display panel according to claim 6, wherein the second power signal line is formed with at least one first air hole, wherein an orthographic projection of the at least one first air hole on the substrate and an orthographic projection of the first via on the substrate are arranged in a staggered manner; and
the first power signal line is formed with at least one second air hole, wherein an orthographic projection of the at least one second air hole on the substrate and an orthographic projection of the second via on the substrate are arranged in a staggered manner.

11. The display panel according to claim 5, wherein the first insulation layer comprises at least one third via, and the lap joint portion is electrically connected to the at least one second wiring structure through the at least one third via.

12. The display panel according to claim 1, wherein the conductive connection layer further comprises a third insulation layer arranged between the first electrode layer and the at least one power signal line;
the third insulation layer comprises at least one fourth via, and the second wiring structure is electrically connected to the at least one power signal line through the fourth via; and
the third insulation layer comprises at least one fifth via, and the second wiring structure extends to the fifth via to be electrically connected to the at least one power signal line.

13. The display panel according to claim 12, wherein the third insulation layer comprises at least one fifth via, the conductive connection layer comprises a first insulation layer arranged between the isolation structure and the first electrode layer and between the at least one power signal line and the isolation structure, and the at least one power signal line comprises one power signal line,
wherein part of the first insulation layer is located in the fifth via and comprises at least one first via located within the fifth via, and the isolation structure is electrically connected to the at least one power signal line through the at least one first via.

14. The display panel according to claim 2, wherein the pixel drive unit comprises at least one switching transistor, and the conductive connection layer further comprises a plurality of third wiring structures, each third wiring structure being electrically connected to each corresponding drive transistor and the at least one corresponding switching transistor.

15. The display panel according to claim 6, wherein the display panel further comprises a light-emitting layer and a pixel defining layer, wherein the pixel defining layer is arranged between the first electrodes and the isolation structure, the pixel defining layer comprises pixel defining portions and pixel openings, the pixel openings are in communication with the corresponding isolation openings, and the pixel openings expose the corresponding first electrodes; and
the light-emitting layer comprises light-emitting units respectively located in the corresponding pixel openings, and the light-emitting units are arranged on a side of the first electrodes away from the substrate.

16. The display panel according to claim 15, wherein the pixel defining portions are made of the same material as the first insulation layer;
second electrodes are arranged on a side of the corresponding light-emitting units away from the substrate; and
the second electrodes are electrically connected to the isolation structure.

17. The display panel according to claim 15, wherein the lap joint portion encloses a first air vent, and an orthographic projection of the first air vent on the substrate and an orthographic projection of the second via on the substrate are arranged in a staggered manner.

18. The display panel according to claim 17, wherein the first insulation layer is formed with a second air vent, and an orthographic projection of the second air vent on the substrate is located within the orthographic projection of the first air vent on the substrate.

19. The display panel according to claim 1, wherein the isolation structure comprises a first sub-layer and a second sub-layer, wherein the first sub-layer is located on a side of the second sub-layer facing the substrate, and an orthographic projection of the first sub-layer on the substrate is located within an orthographic projection of the second sub-layer on the substrate;
the first sub-layer is connected to the at least one power signal line through a via; and
the first sub-layer is connected to the at least one second wiring structure through a via.

20. A display apparatus, comprising:
a display panel, comprising:
a substrate;
a pixel circuit layer arranged on one side of the substrate, wherein the pixel circuit layer comprises a conductive connection layer, and the conductive connection layer comprises at least one power signal line;
a first electrode layer arranged on a side of the conductive connection layer away from the substrate, wherein the first electrode layer comprises at least one second wiring structure and a plurality of first electrodes; and
an isolation structure arranged on sides of the conductive connection layer and the first electrode layer away from the substrate, wherein the isolation structure encloses a plurality of isolation openings, the isolation openings expose the corresponding first electrodes, and the isolation structure is electrically connected to the at least one power signal line and the at least one second wiring structure.
